(19) United States
(12) Patent Application Publication
(10) Pub. No.: US 2010/0317147 A1
(43) Pub. Date: Dec. 16, 2010

(54) METALLIZING DEVICE AND METHOD

(75) Inventor: Armand Bettinelli, Coublevie (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: COMMISSARIAT A L'ENERGIE ATOMIQUE, Paris (FR)

(21) Appl. No.: 12/445,871

(22) PCT Filed: Oct. 23, 2007
(86) PCT No.: PCT/EP2007/061310

§ 371 Date: Apr. 16, 2009

(30) Foreign Application Priority Data
Oct. 24, 2006 (EP) 06 54485

(51) Int. Cl. H01L 31/18; B05C 11/02

(52) U.S. Cl. 438/98; 118/50; 257/E31.11

(57) ABSTRACT

A metallization device configured to metallize a semiconductor device, including: a closed enclosure of variable volume configured to contain a metallization paste, a screen for screen printing forming a wall of the enclosure integral with the other walls of the enclosure, configured to be in contact with the semiconductor device during its metallization, and a mechanism applying uniform pressure over a mobile sealed wall of the enclosure opposite to the wall formed by the printing screen and reducing the volume of the enclosure. The volume reduction of the enclosure is configured to cause the metallization paste to uniformly pass through the printing screen.

### TECHNICAL FIELD AND PRIOR ART

The invention relates to the metallization or production of metal contacts, of semiconductor devices and more particularly to the metallization of photovoltaic cells.

Photovoltaic cells include metallizations either made on the front side, i.e. the side intended to receive light radiation, and on the rear side, or exclusively on the rear side (RCC << Rear Contact Cell >> or IBC << Interdigitated Back Contact >> cells). In order for the cell to receive maximum radiation, the metallizations made on the front side are preferably narrow in order to reduce as much as possible the occupied surface area on the front side of the cell, i.e. to minimize the shadowing on this front side. However, these metallizations must have a sufficient section so as to limit the series resistances, which imposes a thickness all the larger since the conductors are narrower and the resistivity of the material is high.

Metallization by screen printing consists of depositing a significant amount of paste or ink, on a screen of the stencil or web type, and then having the paste pass through the screen by successively scraping this paste on the screen. Only a small volume of the metallization paste passes through the screen at each scraping. The ink is only forced to cross the screen in the area located under the squeegee, this area moving from one side to the other during screen printing.

Stencils are metal plates in which apertures have been made. These stencils are used for producing discontinuous patterns, notably for deposits of soldering paste pads on printed circuits.

If long continuous patterns have to be produced, as this is the case for producing metallizations of photovoltaic cells, screens of the web type are generally used, based on woven threads generally in polyester or steel, the web being locally sealed by the coating of a film or a photosensitive emulsion which has been removed in the areas of the pattern to be produced.

The viscosity of the paste used should be adapted to the geometry of the patterns to be produced.

All the measurements of viscosity given in this document are conducted under the following standard conditions: a viscosity measuring device of the Brookfield HBT™ brand, a rod of type SC4-14/6R, for a speed of rotation of 10 rpm, at a temperature of 25° C., (“Brookfield HBT, SC4-14/6R, @ 10 rpm (25° C.)”).

Pastes for which the viscosity is relatively low (of the order of 50 Pa·s) are used for screen printing on rear sides of photovoltaic cells, where a large surface area has to be covered with this paste, for example based on aluminum. With this low viscosity the screen may be easily detached after spreading of this paste.

Pastes, for example based on silver, of larger viscosity (comprised between about 80 Pa·s and 300 Pa·s) are used for screen printing of narrow conductors on the front side of the photovoltaic cell.

This viscosity range, which is the only one available commercially for producing metallizations on the front side of photovoltaic cells, was selected because it allows the paste to properly pass through the web used for screen printing. Further, when a web is used for screen printing, the paste is not transferred under the crossing points of the threads of the web. With such a viscosity, the paste transferred in the mesh apertures is spread in order to form a rather regular continuous pattern. Finally, with this viscosity range, the screen printing paste may also not block the patterns of the screen used during screen printing.

Screen printing is an economical technique because of its high productivity, but leads to a limited height/width form factor for metallizations. Typically, metallizations produced by screen printing on a photovoltaic cell have a width comprised between about 100 μm to 200 μm and a thickness comprised between about 10 μm and 20 μm.

Problems related to evaporation of the solvents found in the metallization paste also occur during screen printing. This evaporation may be an obstacle for properly metallizing the semiconductor device. Further, during screen printing, the metallization paste is subject to shear movements due to scraping, involving a reduction in the viscosity of the paste and causing an untimely spreading of this metallization paste.

### DISCUSSION OF THE INVENTION

An object of the present invention is to propose a device with which a semiconductor device may be metallized by getting rid of the problems of evaporation of the solvents and of spreading of the metallization paste, encountered during screen printing.

For this, the present invention proposes a metallization device intended to metallize a semiconductor device, including:
a closed enclosure of variable volume intended to contain a metallization paste,
a screen for screen printing forming one of the walls of the enclosure, intended to be in contact with the semiconductor device during its metallization,
means for applying uniform pressure over a mobile sealed wall of the enclosure and for reducing the volume of the enclosure,

the reduction in volume of the enclosure being intended to have the metallization paste uniformly pass through the printing screen.

The mobile sealed wall of the enclosure may be a wall opposite to the wall formed by the printing screen.

The printing screen may form a wall of the enclosure integral with the other walls of the enclosure.

With such a device, the metallization paste is placed in a closed location, preventing evaporation of the solvents present in the paste during the metallization of the semiconductor device. On the other hand, by the uniform pressure exerted on the mobile sealed wall of the enclosure during metallization, the paste passes through the whole surface of the screen at the same time, thereby metallizing the whole of the semiconductor device simultaneously. Uniform pressure substantially perpendicular to the semiconductor device is ensured on the whole of the semiconductor device which limits the problems of local friction at the semiconductor device encountered with devices of the prior art.

Further, the viscosity of the metallization paste does not decrease because it is not subject to a significant shear rate as in conventional screen printing. Therefore, there is no untimely spreading of this paste during the metallization of the semiconductor device.

The present invention particularly applies to the metallization of a photovoltaic cell, for example on the front side, but generally relates to metallization of any type of semiconductor device.

The printing screen may include:
at least one first layer comprising a first side intended to be in contact with the semiconductor device during its metallization and a second side opposite to the first side, and at least one aperture opening out at said two sides of the first layer and forming a metallization pattern of the semiconductor device,
at least one second layer comprising a first side positioned against the second side of the first layer and a second side opposite to its first side, comprising at least one aperture formed by a plurality of orifices and opening out at said two sides of the second layer, the pattern formed by the aperture of the second layer being included in the metallization pattern of the semiconductor device when these patterns are superposed into each other.

Thus, the first layer may have one or several apertures, the pattern of which (for example a line) forms the pattern of the metallizations to be produced. The aperture(s) of the second layer are formed by orifices allowing injection of the metallization paste into the aperture(s) of the first layer, and allowing the metallization paste to retain lateral stability during the whole screen printing step.

By means of this screen, injection of the paste and detachment of the screen may be optimized by selecting the shape and the size of the orifices forming the aperture(s) of the second layer and by thereby varying the surface area ratio between the aperture(s) of the second layer and the aperture(s) of the first layer.

Finally, by means of the geometry of this screen (an injection area only in the high portion), it is unnecessary to produce a coating of the deposited metallization paste in order to obtain electrically continuous metallizations. Further, it is possible to transfer a larger amount of metallization paste than with the methods of the prior art, thereby forming less resistive conductors.

Advantageously, the thickness of the first layer determining the height of the lower portions of the deposited metallizations, may be larger than that of the second layer.

The dimensions of the aperture of the first layer at the first side may be larger than the dimensions of the aperture at the second side. Such an aperture may be made by electrodeposition. With this configuration, it is possible to more easily separate the screen from the metallization paste after depositing the metallization paste.

The means for applying a pressure may be a fluid.

The device, object of the present invention, may further include a sealed membrane and a solid reservoir in which the sealed membrane is positioned and in which the means for applying pressure are positioned.

The present invention also relates to a method for metallizing a semiconductor device, including at least one step for depositing a metallization paste on the semiconductor device, applied by the metallization device, also object of the present invention, as described above.

The metallization paste may have a viscosity larger than or equal to about 350 Pa·s, or preferably larger than or equal to about 400 Pa·s, or advantageously comprised between about 400 Pa·s and about 1200 Pa·s, or preferably comprised between about 600 Pa·s and about 1000 Pa·s.

This increase in the viscosity of the metallization paste as compared with the metallization pastes used in the methods of the prior art, may be obtained by reducing the proportion of binders in the composition of the metallization paste. This increase in the viscosity may also be obtained by adding a flow additive, for example a thixotropic agent.

By using such a metallization paste, it is for example possible to make narrow and high conductors, reducing the surface area occupied on a front side of a photovoltaic cell as compared with the conductors made according to the methods of the prior art. This therefore leads to an increase in the conversion yield of a photovoltaic cell which is thereby metallized at the front side, because of an increase in the current produced by the cell (less shadowing formed by the metallizations on the front side) and of the improvement of the form factor (decrease of the series resistance of these metallizations). Also, producing metallizations on the rear side of a photovoltaic cell with this method, object of the present invention, is particularly useful when constraints on resistance require the making of narrow conductors.

By using a paste with a higher viscosity, with limited spreading of this paste after its deposit, it is possible to obtain narrower and thicker conductors for a same transferred volume of paste.

By using such a metallization paste, the thickness of the obtained metallization after drying is larger because of the reduction in volume loss related to evaporation of the solvent(s) present in the binders. Further, baking of the paste is facilitated by the reduction in the amount of resin to be burnt (case of the pastes of the prior art dedicated to the method for metallizing photovoltaic cells with high temperature baking).

The reduction in the amount of binders also means that the metal content of the paste is larger as compared with the metal content of a paste of equivalent composition but of lower viscosity. This is particularly true for paste of the prior art (viscosity comprised between 80 Pa·s and 300 Pa·s) dedicated to the methods for metallizing photovoltaic cells with low temperature (for example 180° C.) baking, for example for cells including heterojunction structures. In these so-called “low temperature” metallization pastes, the organic portion is not a temporary binder but a resin which, by polymerizing, applies the metal particles against each other, the resistivity therefore not being improved by sintering reactions.

By the joint use of a paste with strong viscosity and a dual layer screen as described earlier, after depositing the metallization paste, it is possible to separate the screen from the metallization paste without detaching the paste in spite of its strong viscosity. Unlike a web type screen where the threads perpendicular to each other overlap, the area for injecting the paste is only located in the high portion, therefore not covered with paste during scraping.

### SHORT DESCRIPTION OF THE FIGURES

The present invention will be better understood upon reading through the description of exemplary embodiments given purely as an indication and by no means as a limitation, with reference to the appended figures wherein:

FIGS. 1A and 1B illustrate a metallization device, object of the present invention, according to a first embodiment,

FIGS. 2A and 2B illustrate an exemplary printing screen used in a metallization device, object of the present invention,

FIGS. 3A, 3B respectively illustrate a metallization device, object of the present invention, according to a first and second alternative of the first embodiment,

FIG. 4 illustrates a metallization device, object of the present invention, according to a second embodiment.

Identical, similar or equivalent portions of the different figures described hereafter bear the same numerical references so as to facilitate the transition from one figure to the next.

The different portions illustrated in the figures are not necessarily illustrated according to a uniform scale so as to make the figures more legible.

The different possibilities (alternatives and embodiments) should be understood as not being exclusive of each other and they may be combined together.

### DETAILED DISCUSSION OF PARTICULAR EMBODIMENTS

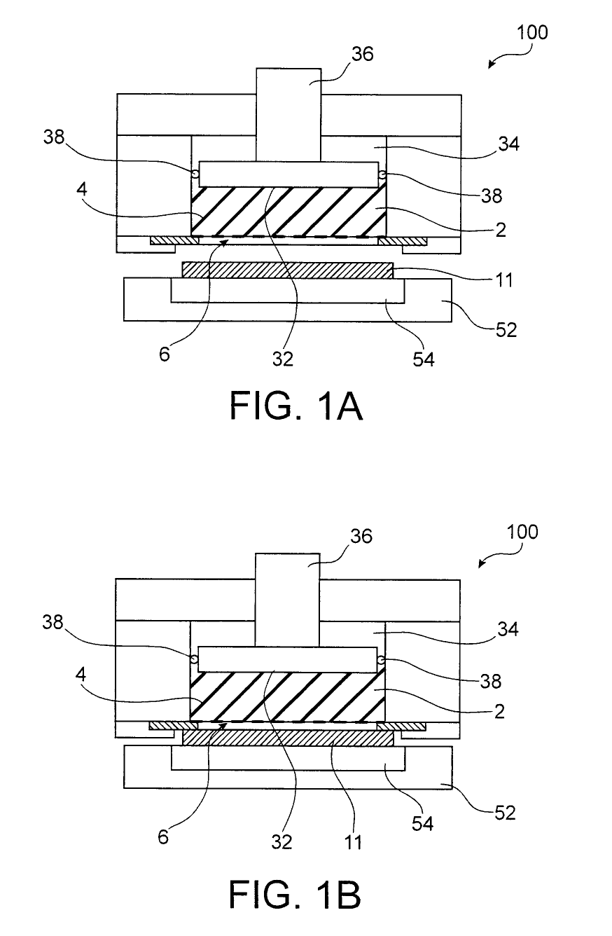

First of all, reference will be made to FIG. 1A which illustrates a metallization device 100 according to a first embodiment.

The metallization device 100 includes a closed enclosure 2 of variable volume intended to contain the metallization paste 4. In this first embodiment, a semiconductor device 11 intended to be metallized by the metallization device 100 is photovoltaic cell.

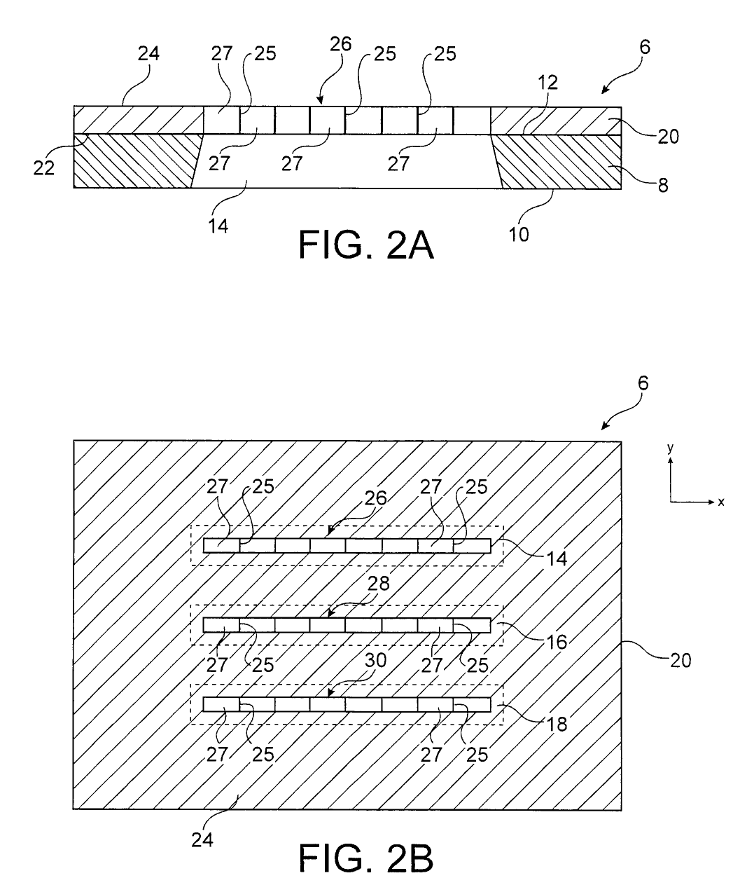

A printing screen 6 forms one of the walls of the enclosure 2. This printing screen 6 may for example be a screen of the stencil or web type. In this first embodiment, the printing screen 6 is a dual layer screen as described later on in connection with FIGS. 2A and 2B.

In the metallization device 100, the closed enclosure 2 is made in such a way that the application of a force or pressure on a mobile sealed wall 32 of the enclosure 2 opposite to the wall formed by the printed screen 6 causes a reduction in the volume of the enclosure 2. With this volume reduction of the enclosure 2 it is possible to cause the metallization paste 4 to uniformly pass through the printing screen 6. This pressure causing the metallization paste 4 to pass through the screen 6 is applied when the printing screen 6 is in contact with the semiconductor device 11 to be metallized, as this is the case in FIG. 1B.

In this first embodiment of the metallization device 100, the closed enclosure 2 is formed by a solid reservoir 34 in which a piston 36 slides, a portion of the piston 36 forming the mobile sealed wall 32 of the enclosure 2 opposite to the wall formed by the printing screen 6. A seal gasket 38 placed at the periphery of the piston 36 cooperates with the latter in order to form the mobile sealed wall 32. In one alternative, a plaque, for example an elastomer, might have been inserted between the piston 36 and the metallization paste 4 as a replacement for the gasket 38 in order to provide the seal of the mobile wall 32.

When the device 100 is not metallizing the semiconductor device 11, slight pressure is applied to the piston 36 so that the metallization paste 4 remains very slightly compressed without exceeding the flow threshold, i.e. without it passing through the printing screen 6.

FIGS. 2A and 2B respectively illustrate a sectional view and a top view of an exemplary embodiment of a printing screen 6 of the metallization device 100. It is seen in FIG. 2A that this screen 6 includes a first layer 8. A first side 10 is intended to be in contact, during the screen printing step, with the semiconductor device 11 which has to be metallized. This first layer 8 also includes a second side 12 opposite to the first side 10. The printing screen 6 includes three apertures 14, 16, 18, opening out at both sides 10, 12 of the first layer 8, formed in the first layer 8. In FIG. 2A, only the aperture 14 is illustrated. In the example of FIGS. 2A and 2B, the aperture 14 is a slot with a trapezoidal section, but any other geometry is conceivable.

Thus, this aperture 14 forms a pattern for metallizing the semiconductor device 11, for example for making metallization buses of photovoltaic cell. In this example, the dimensions of the aperture 14 at the first side 10 are larger than the dimensions of the aperture 14 at the second side 12, producing a metallization including a wider base than the remainder of the metallization.

The screen 6 includes a second layer 20 comprising a first side 22 positioned against the second side 12 of the first layer 8 and a second side 24 opposite to its first side 22. As illustrated in FIG. 2A, both layers 8 and 20 are positioned against each other. This second layer 20 comprises three apertures 26, 28, 30, each formed by a plurality of orifices 27 and opening out at both sides 22, 24 of the second layer 20. By superposing the layers 8 and 20, the pattern formed by each of the apertures 26, 28, 30 is included in the metallization pattern, i.e. the pattern formed by each of the apertures 14, 16, 18. In the example of FIGS. 2A and 2B, the orifices 27 forming each aperture 26, 28, 30 are as large as possible and limited by portions of material 25 ensuring that the geometry of the layer 10 is maintained. In FIGS. 1 and 2, the orifices 27 for example have a dimension along the x axis (illustrated in FIG. 2B) equal to about 50 μm. This dimension may also be comprised between about 50 μm and 200 μm. In FIG. 2B, it is seen that the orifices 27 are of a rectangular shape and positioned in line.

In this exemplary embodiment, the first layer 8 has a larger thickness than that of the second layer 20, but both layers 8, 20 may also have substantially identical thickness. In another exemplary embodiment, the first layer 8 may also have a smaller thickness than that of the second layer 20.

The metallization paste 4 used by the metallization device 100 may for example have a viscosity larger than or equal to about 350 Pa·s.

A metallization paste with a viscosity greater than or equal to about 350 Pa·s may be obtained by mixing various raw materials. These raw materials are for example:
a solvent with a high boiling temperature (for example 219° C.), thereby limiting its evaporation, such as terpineol,
a very low viscosity resin, such as ethyl-cellulose with a low viscosity grade, for example N4 (Hercules),
spherical fine silver powders, the diameter of which may be of a medium size, for example of the order of one μm, or flakes with a size less than 10 μm, or a mixture of both,
glass sinter in proportions similar to those used for metallization pastes of the prior art.

A pasting of these raw materials is then carried out by dispersing these particles of raw materials into the binder. For this, kneading may be carried out first slowly in order to wet the particles, and then more rapidly for improving their dispersion. This kneading may be performed for example with a kneader of the butterfly blade type. With refining, by using for example a tricylinder or a contactless mixer associating rotation and revolution, for example of the VMX-N360 type of EME™, it is then possible to obtain the metallization paste used in the metallization method described earlier. Other methods for increasing the viscosity of the paste are possible, for example by adding a thixotropic agent.

Metallization pastes with a viscosity larger than or equal to 350 Pa·s may also be obtained by “reloading” commercial pastes with a viscosity comprised between about 80 Pa·s and 300 Pa·s, i.e. by adding materials to these pastes. The reloading material may for example be metal particles or a mixture of metal particles and glass sinter, particles having sufficient fineness so that fine metallizations may be produced, or further glass sinter preferably pre-dispersed in silver. Silver powders, for example similar to those described earlier, may also be used for reloading commercial pastes. The pasting and refining achieved after adding these materials are, as described earlier, adapted to the high viscosities of the obtained pastes.

In order to achieve metallization of the semiconductor device 11, the device 11 to be metallized is first of all positioned in front of a printing screen 6, on a support 52 for example in metal or in hard elastomer (for example with a hardness above about Shores). Advantageously, the device 11 may be mechanically and/or optically aligned with the printing screen 6. The metallization device 100 may for example include in this first embodiment, cooling means 54 integrated to the support 52 receiving the device 11 to be metallized. With these cooling means, it will be possible to “set” the metallization paste 4 deposited on the device 11 by suddenly increasing its viscosity. These cooling means are advantageously used when the metallization paste 4 is heated in the enclosure 2 in order to facilitate its extraction as this is described later on in the description.

The semiconductor device 11 to be metallized and the printing screen 6 are then brought into contact against each other, as illustrated in FIG. 1B. In this first embodiment, it is the upper portion of the metallization device 100 which includes the closed enclosure 2 and the piston 36 that is displaced towards the semiconductor device 11.

The piston 36 then applies pressure on the metallization paste 4, thereby reducing the volume of the enclosure 2 and transferring metallization paste 4 onto the semiconductor device 11 through the printing screen 6. The pressure to be applied is all the larger since the surface area of the apertures formed in the printing screen 6 is large and the viscosity of the paste is high. The reduction in volume of the enclosure 2 is very small and corresponds to the volume of the metallization paste 4 transferred into the apertures 14, 16, 18, 26, 28 and 30 of the printing screen 6.

Once the metallization paste 4 is deposited on the semiconductor device 11, the printing screen 6 is then separated from the semiconductor device 11 by moving back the upper portion upwards (piston 36 and closed enclosure 2) of the metallization device 100. This separation is facilitated by the dual layer structure of the screen 6 and because the metallization paste used contains less binder than the standard metallization pastes. Even if the metallization paste 4 has strong viscosity (>350 Pa·s), with the dual layer structure of the screen 6, it may be removed without risking detachment of the deposited metallization paste. Further, the elasticity of the support 52 in hard elastomer promotes the screen/metallization paste separation without any damage.

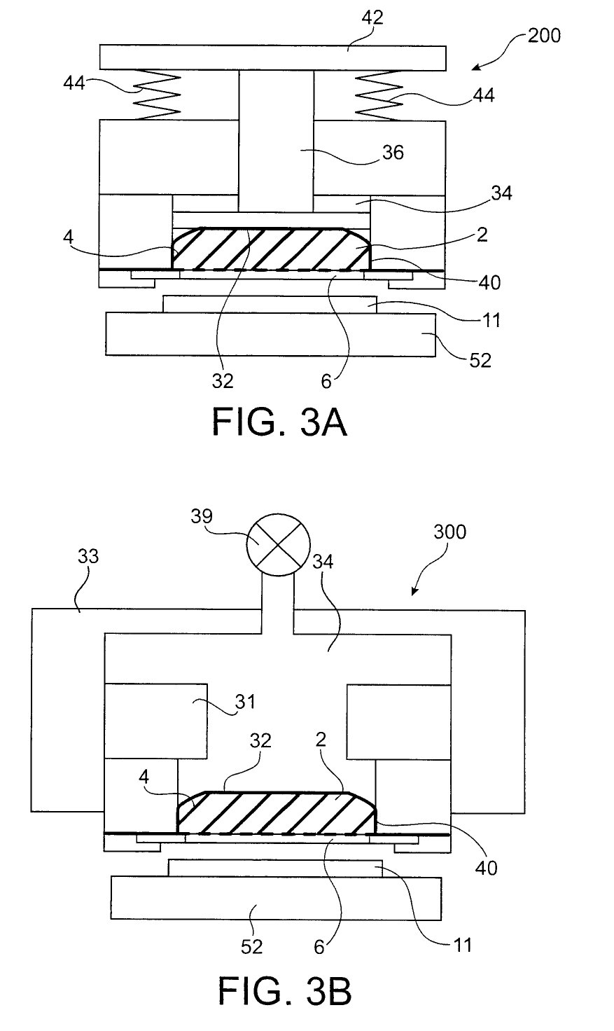

FIG. 3A illustrates a metallization device 200 according to a first alternative of the first embodiment. In this first alternative, the seal of the wall 32 is not provided by a seal gasket but by a sealed membrane 40, for example based on elastomer, forming by itself the sealed wall 32. Compared with the first embodiment, it is not the solid reservoir 34 that forms the enclosure 2, but the sealed membrane 40, which is positioned in the solid reservoir 34.

In this first alternative of the first embodiment, pressure is applied onto a component 42 connected to the piston 36. This pressure first of all causes the upper portion of the device 200 to move down, portion formed by the closed enclosure 2 and the piston 36, until the printing screen 6 is in contact with the semiconductor device 11. The pressure applied to the piston 36 then pushes the metallization paste 4 through the printing screen 6. When the device 200 is at rest, i.e. it is not injecting metallization paste onto the semiconductor device 11 to be metallized, springs 44 adjusted so as to be active in traction, are used for pressurizing the enclosure 2 slightly below the flow threshold of the metallization paste so that the latter does not flow.

FIG. 3B illustrates a metallization device 300 according to a second alternative of the first embodiment. As compared with the device 200 of FIG. 3A, the pressure is not applied by a piston 36 but directly by a fluid injected into the solid reservoir 34 by a pump 39. When the device 300 is at rest, i.e. when it is not injecting metallization paste 4 onto the semiconductor device 11 to be metallized, the fluid exerts slight pressure in the enclosure 2 so that the metallization paste 4 is slightly compressed, but remains below its flow threshold. In order to deposit the metallization paste 4 onto the semiconductor device 11, stronger pressure is applied via the fluid on a portion 31 of the device 300, mobile relatively to a fixed portion 33 of the device 300. The mobile portion 31 moves down until the printing screen 6 is in contact with the semiconductor device 11.

Next, the pressure applied by the fluid is exerted on the membrane 40, then pushing the metallization paste 4 through the printing screen 6 onto the semiconductor device 11.

This alternative embodiment has the advantage of exerting uniform pressure over the whole surface of the membrane 40.

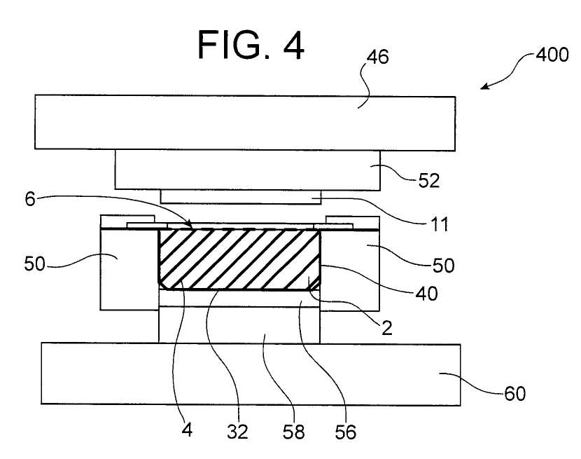

FIG. 4 illustrates a metallization device 400 according to a second embodiment. This device 400 includes an upper portion formed by a plate 46, bound to a support 52 intended to receive the semiconductor device 11.

The metallization device 400 includes a lower portion including a solid reservoir formed by the sidewalls 50 and a component 58 forming a bottom wall, the sidewalls 50 being translationally mobile relatively to the component 58. A closed enclosure 2 formed by a sealed membrane 40 is positioned in the solid reservoir. A plate 60 supports the components of the lower portion of the metallization device 400. Regulation means 56, such as a plate based on a heat conducting material including an integrated piping network allowing circulation of a temperature-regulated fluid, allows the temperature to be controlled inside the enclosure 2 and to be regulated in order to, for example, temporarily decrease the viscosity of the paste so as to facilitate injection by raising the paste to a temperature above room temperature, for example to about 35° C.

In order to achieve metallization of the semiconductor device 11, pressure is applied on the plate 46, by moving down the upper portion of the metallization device 400 until the printing screen 6 is in contact with the device 11 to be metallized. By continuing to apply pressure on the plate 46, this pressure is transmitted to the sidewalls 50, making them move down relatively to the components 56, 58 thereby reducing the volume of the closed enclosure 2 and causing the metallization paste 4 to pass through the printing screen 6.

Once the metallization paste 4 is deposited on the semiconductor device 11, the printing screen 6 is then separated from the semiconductor device 11 by moving back the upper portion upwards (plate 46, support 52 and semiconductor device 11) of the metallization device 400.

In an alternative of this second embodiment, pressure may be applied onto the plate 60, causing displacement of the lower portion (plate 60, walls 50, components 56, 58 and solid reservoir) of the metallization device 400 upwards. When the printing screen 6 is in contact with the device 11 to be metallized, the pressure applied to the plate 60 causes translation of the components 56, 58 relatively to the sidewalls 50, thereby reducing the volume of the enclosure 2 and achieving metallization of the semiconductor device 11.

With such a metallization device, for example combined with a dual layer printing screen, and with a metallization paste with a viscosity larger than about 350 Pa·s, for example comprised between about 800 Pa·s and 900 Pa·s, it is possible to obtain metallizations, with a high form factor, for example of the order of 0.5 for a metallization paste with a viscosity equal to about 900 Pa·s, ideal for narrow conductors of photovoltaic cells (for example, narrow conductors with a width equal to about 80 μm and a thickness equal to about 40 μm)

Such a metallization device may be placed in the head of a screen printing machine, as a replacement for the screen-holder and squeegee assembly used during standard screen printing. This head is sufficiently robust in order to apply sufficient pressure so that the paste may be properly injected regardless of the viscosity of the metallization paste used. The metallization device may for example be placed in a press, for example similar to a die-stamping press, thus providing sufficient pressure for achieving metallizations and being well adapted to high productivity.

1-18. (canceled)

19. A metallization device configured to metallize a semiconductor device, comprising:
a closed enclosure of variable volume configured to contain a metallization paste;
a screen for screen printing forming a wall of the enclosure integral with other walls of the enclosure, configured to be in contact with the semiconductor device during its metallization;
means for applying uniform pressure over a mobile sealed wall of the enclosure and for reducing the volume of the enclosure;
the volume reduction of the enclosure being configured to cause the metallization paste to uniformly pass through the printing screen.

20. The device according to claim 19, the mobile sealed wall being a wall opposite to the wall formed by the printing screen.

21. The device according to claim 19, the printing screen comprising:
at least one first layer comprising a first side configured to be in contact with the semiconductor device during its metallization and a second side opposite to the first side, and at least one aperture opening out at the two sides of the first layer and forming a metallization pattern of the semiconductor device,
at least one second layer comprising a first side positioned against the second side of the first layer and a second side opposite to its first side, comprising at least one aperture formed by a plurality of orifices and opening out at the two sides of the second layer, the pattern formed by the aperture of the second layer being included in the metallization pattern of the semiconductor device when these patterns are superposed into each other.

22. The device according to claim 21, the thickness of the first layer being larger than the thickness of the second layer.

23. The device according to claim 21, the orifices of the aperture of the second layer being of rectangular shape and positioned in line.

24. The device according to claim 21, dimensions of the aperture of the first layer at the first side being larger than dimensions of the aperture at the second side.

25. The device according to claim 19, further comprising a support configured to support the semiconductor device during its metallization.

26. The device according to claim 19, further comprising cooling means for cooling the semiconductor device integrated to the support.

27. The device according to claim 19, the means for applying pressure including a fluid.

28. The device according to claim 19, the means for applying pressure including a piston.

29. The device according to claim 28, further comprising a seal gasket cooperating with the piston to form the mobile sealed wall of the enclosure.

30. The device according to claim 28, the walls other than the mobile sealed wall of the enclosure being formed by a solid reservoir wherein the piston slides.

31. The device according to claim 19, further comprising a sealed membrane forming the enclosure.

32. The device according to claim 31, further comprising a solid reservoir wherein the sealed membrane is positioned and wherein the means for applying pressure are positioned.

33. The device according to claim 19, further comprising means for regulating the temperature of the enclosure.

34. A method for metallizing a semiconductor device, comprising:
depositing a metallization paste on the semiconductor device applied by the metallization device according to claim 19.

35. The method according to claim 34, the metallization paste having a viscosity larger than or equal to about 350 Pa·s.

36. The method according to claim 34, the semiconductor device including a photovoltaic cell.
